(19) United States
(12) Patent Application Publication
(10) Pub. No.: US 2007/0120186 A1
(43) Pub. Date: May 31, 2007

(54) Engineered barrier layer and gate gap for transistors with negative differential resistance

(75) Inventors: Qiang Lu, Foster City, CA (US); Tsu-Jae King Liu, Fremont, CA (US)

Correspondence Address: BEVER, HOFFMAN & HARMS, LLP, 2099 GATEWAY PLACE, SUITE 320, SAN JOSE, CA, 95110, US

(73) Assignee: Synopsys, Inc., Mountain View, CA (US)

(21) Appl. No.: 11/290,337

(22) Filed: Nov. 29, 2005

(51) Int. Cl. H01L 29/76; H01L 29/94; H01L 31/00

(52) U.S. Cl. 257/345

(57) ABSTRACT

A negative differential resistance (NDR) transistor includes a gate stack formed from a gate, a barrier layer, and a dielectric layer formed between the gate and barrier layer. To enable the NDR characteristic of the transistor, the barrier layer is configured to dynamically transfer charge carriers to and from the channel region of the transistor (e.g., to a charge storage node between the barrier layer and the dielectric layer), thereby adjusting the threshold voltage of the transistor. An NDR transistor can also be formed with a gap between the edge of the source region and the edge of the gate (stack) to enhance the electric field in the portion of the channel region corresponding to the gap. The enhanced electric field can concentrate the distribution of charge carriers removed from the channel region in the proximity of the source region, thereby enhancing the NDR performance of the transistor.

### BACKGROUND OF THE INVENTION

1. Field of the Invention

The invention relates to the field of semiconductor devices, and in particular, to a metal-insulator-semiconductor device that exhibits negative differential resistance behavior.

2. Related Art

Negative differential resistance (NDR) transistors can beneficially be used in a great number of integrated circuit designs to simplify circuit complexity and improve performance. An NDR transistor is a transistor that exhibits a negative differential resistance characteristic in response to variations in drain-to-source voltage. Specifically, the drain current through the transistor increases with increasing drain-to-source voltage until a threshold voltage (referred to as the “NDR voltage”) is reached, at which point the drain current rapidly decreases with further increases in drain-to-source voltage.

FIG. 1 shows a graph 100 of drain current (i.e., drain-to-source current) I_{DS} for a fixed gate bias voltage (i.e., gate-to-source voltage) as a function of drain-to-source voltage V_{DS}. In a standard operating region 110 (i.e., drain-to-source voltage V_{DS} less than NDR voltage V_{NDR}), drain current I_{DS} increases with increasing drain-to-source voltage V_{DS} (similar to the behavior of a standard metal-oxide-semiconductor (MOS) transistor). However, in an NDR operating region 120 (i.e., drain-to-source voltage V_{DS} equal to at least NDR voltage V_{NDR}), drain current I_{DS} decreases rapidly with increasing drain-to-source voltage V_{DS}. This rapid decrease in drain current I_{DS} represents the NDR characteristic of the NDR transistor.

Key figures of merit for an NDR transistor include the NDR voltage V_{NDR}, the “peak to valley ratio” (PVR), and the NDR switching speed of the device. As noted above, the NDR voltage V_{NDR} is the drain-to-source voltage V_{DS} at which the NDR behavior of the device begins. The drain current I_{DS} at this point is the maximum drain current (i.e., the “peak current”) for the device, and can be compared to the minimum drain current (i.e., the “valley current”) achievable in the NDR operating region 120 for the device to determine the PVR for the device. In general, a high PVR ratio is desirable to maximize the performance of circuits incorporating NDR transistors. In addition, a relatively low NDR voltage V_{NDR} is often desirable to implement power-efficient IC designs. Finally, a fast NDR switching speed for the NDR transistor (i.e., the speed at which drain current I_{DS} transitions from the peak current to the valley current, or vice versa) beneficially optimizes the overall speed of an IC that incorporates the NDR transistor.

Previous NDR transistors have been implemented as metal-oxide-semiconductor (MOS) devices that incorporate charge traps that provide dynamic threshold voltage adjustments to provide the NDR effect. Such a device is described in co-owned U.S. Pat. No. 6,512,274, issued Jan. 28, 2003 to King et al., herein incorporated by reference. FIG. 2A shows an NDR FET (field effect transistor) 200 according to the King et al. application. NDR FET 200 includes a source region 240 and a drain region 250 formed in a substrate 210. Source region 240 and drain region 250 define a channel region 260 in substrate 210, over which a dielectric 230 and a gate 220 are formed.

NDR FET 200 differs from a standard MOS device in that NDR FET 200 includes a multitude of charge traps 231 (sometimes referred to as “charge trapping sites”) at the interface between dielectric 230 and channel region 260. When a gate voltage V_{G} at gate 220 provides a sufficient gate bias that is high enough to turn on NDR FET 200 (i.e., gate voltage V_{G} is sufficiently greater than a source voltage V_{S} at source 240), drain current through NDR FET 200 will exhibit the NDR characteristic depicted in the graph of FIG. 1. As the drain-to-source voltage V_{DS} (i.e., the difference between a drain voltage V_{D} at drain 250 and source voltage V_{S}) increases, the lateral electric field in channel region 260 increases, thereby causing energized electrons to flow from source 240 to drain 250. Increasing drain-to-source voltage V_{DS} increases the strength of this electric field, resulting in greater electron flow across channel region 260 (and hence, increased drain current I_{DS} through NDR FET 200).

Note that a vertical electric field also exists in channel region 260 due to gate voltage V_{G} (a body (“bulk”) voltage V_{B} supplied to substrate 210 is typically equal to source voltage V_{S} to prevent the body effect from affecting the threshold voltage of the device). This vertical electric field generates the inversion layer within channel region 260 that allows electron flow between source 240 and drain 250. However, this vertical electric field also tends to draw the electrons in channel region 260 towards dielectric 230. When the drain-to-source voltage V_{DS} reaches a threshold value (i.e., NDR voltage V_{NDR}), sufficient kinetic energy is imparted to electrons in channel region 260 to allow a portion of those electrons to be captured by charge traps 231. This accumulation of electrons at the interface between channel region 260 and dielectric 230 dynamically increases the threshold voltage of NDR FET 200, thereby reducing the inversion layer charge density and inhibiting current flow in channel region 260 (i.e., reducing the drain current I_{DS} of NDR FET 200). As the drain-to-source voltage V_{DS} increases, the quantity of electrons trapped in charge traps 231 increases, which in turn dramatically decreases the current I_{DS} flowing through NDR FET 200, as indicated by the large negative slope of graph 100 in the NDR operating region 120 of FIG. 1.

FIG. 2B shows an exemplary energy band diagram (electron energy vs. distance in the direction perpendicular to substrate 210) for NDR FET 200. A lower edge E_{C} for the conduction band of allowed electron energy states for semiconductor substrate 210 is shown, as well as an upper edge E_{V} for the valence band of allowed electron energy states. Conventional device physics theory mandates that no allowed electron energy states exist within the band gap defined between edges E_{V} and E_{C}. Therefore, mobile electrons in substrate 210 cannot exhibit energies within this range. As indicated by the position of charge trap 231, the charge traps 231 in NDR FET 200 are selected to have energy levels just above the lower edge E_{C} of the conduction band, and can therefore trap electrons (particularly hot carriers) having energy states within the conduction band of substrate 210. Note, however, that because charge trap 231 is only slightly above the lower edge E_{C} of the conduction band, an electron trapped by charge trap 231 can easily move back into an allowed energy state within the conduction band (i.e., the electron is easily “de-trapped”). Accordingly, charge traps 231 allow charge carriers from channel region 260 to be dynamically trapped and detrapped in response to drain-to-source voltage V_{DS}.

The relatively weak trapping of electrons at the interface between channel region 260 and dielectric 230 beneficially enhances the NDR behavior of NDR FET 200 by allowing the NDR characteristic to be highly responsive to drain-to-source voltage V_{DS}. Specifically, the fast trapping/detrapping mechanism provided by charge traps 231 allows NDR FET 200 to exhibit a fast NDR switching speed, as the charge trapping behavior of charge traps 231 can react quickly to changes in drain-to-source voltage V_{DS}. Although the total number of electrons trapped for a given drain-to-source voltage V_{DS} will be relatively constant (because the rate of charge trapping and de-trapping associated with that given drain-to-source voltage V_{DS} will tend to maintain a steady state accumulation of electrons within charge traps 231), any changes in drain-to-source voltage V_{DS} will quickly result in a new steady state level of electron accumulation within charge traps 231 that will in turn determine the drain current I_{DS} flowing through NDR FET 200.

In this manner, NDR FET 200 can provide NDR behavior in a three-terminal device. However, in certain circumstances, accurately controlling the characteristics and distribution of charge traps 231 in dielectric 230 can be difficult, which in turn can increase the difficulty in achieving a particular NDR voltage, PVR, and/or NDR switching speed for NDR FET 200. Accordingly, it is desirable to provide an alternative NDR MOSFET design to increase manufacturing flexibility.

### SUMMARY OF THE INVENTION

In a negative differential resistance (NDR) transistor, it is desirable to be able to optimize the device characteristics, such as peak-to-valley ratio (PVR), NDR voltage, for different applications/technologies. In conventional NDR transistors, these characteristics are controlled by the distribution of charge traps at the gate dielectric/channel region interface. However, in certain circumstances, accurately controlling the charge trap distribution, and hence, accurately controlling the PVR, NDR voltage, and/or NDR switching speed values for the NDR transistor, can be difficult. By replacing the charge traps with a barrier layer and a charge storage node (layer) in the gate dielectric, greater manufacturing flexibility and improved control over NDR transistor characteristics can be achieved. As a separate approach, by introducing a gap between the source-channel junction and the gate, the electric field within that gap can be significantly enhanced, thereby reducing the NDR voltage. improving the PVR, and increasing the NDR switching speed of the NDR transistor.

In one embodiment, an NDR transistor can include a gate stack formed from a barrier layer, a dielectric layer formed over the barrier layer, and a gate formed on the dielectric layer. The barrier layer is configured to dynamically transfer charge carriers (e.g., electrons or holes) to and from the channel region of the transistor (e.g., to an from an optional charge storage node between the barrier layer and the dielectric layer) in response to the drain-to-source voltage applied to the transistor. The permittivity of the barrier layer should therefore be greater than the permittivity of the dielectric layer to prevent current flow through the gate of the transistor. By configuring the barrier layer to provide a low channel region-to-barrier layer potential barrier height, and a low charge storage node-to-barrier layer potential barrier height, a low NDR voltage and high NDR switching speed, respectively, can be provided for the NDR transistor. Achieving such NDR performance through appropriate engineering of the barrier layer can be easier than creating the specific distribution of charge traps in a dielectric layer that would be required in a charge trap-based NDR transistor.

In another embodiment, the gate stack of an NDR transistor can be constructed such that the stack does not extend to the edge of the source region in the transistor. Specifically, the gate does not overlie a portion of the channel region that is immediately adjacent to the source region of the transistor (for manufacturing purposes, a similar underlap will typically be exhibited at the drain region of the transistor as well). The electric field in this portion of the channel region that is not covered by the gate stack will then be enhanced, due to the reduced inversion layer in that region. Consequently, charge carrier removal from the channel region during operation of the NDR transistor will be concentrated towards the source region of the transistor, thereby causing the NDR characteristic of the transistor to manifest more quickly and at a lower NDR voltage than would normally occur if the electric field were more constant across the channel region. The increased concentration of trapped/stored charge carriers in the vicinity of the source region can also reduce the valley current of the NDR transistor. Note that the benefits of this electric field modification can be applied to any type of NDR transistor (e.g., charge trap-based transistors or barrier layer-based transistors).

The invention will be more fully understood in view of the following description and drawings.

### BRIEF DESCRIPTION OF THE DRAWINGS

FIG. 1 is an exemplary graph of drain current versus drain-to-source voltage for an NDR transistor.

FIG. 2A is an NDR FET that includes charge traps.

FIG. 2B is an energy band diagram for the NDR FET of FIG. 2A.

FIG. 3A is an NDR FET that includes a barrier layer and charge storage node to provide NDR functionality.

FIG. 3B is an energy band diagram for the NDR FET of FIG. 3A.

FIGS. 4A and 4B are NDR FETs that include gate-source “gaps” to provide localized charge trapping.

### DETAILED DESCRIPTION

In a negative differential resistance (NDR) transistor, it is desirable to be able to optimize the device characteristics, such as peak-to-valley ratio (PVR), NDR voltage, for different applications/technologies. In conventional NDR transistors, these characteristics are controlled by the distribution of charge traps at the gate dielectric/channel region interface. However, in certain circumstances, accurately controlling the charge trap distribution, and hence, accurately controlling the PVR, NDR voltage, and/or NDR switching speed values for the NDR transistor, can be difficult. By replacing the charge traps with a barrier layer and a charge storage node (layer) in the gate dielectric, greater manufacturing flexibility and improved control over NDR transistor characteristics can be achieved. As a separate approach, by introducing a gap between the source-channel junction and the gate, the electric field within that gap can be significantly enhanced, thereby improving the PVR, reducing the NDR voltage, and increasing the NDR switching speed of the NDR transistor.

NDR Barrier Engineering

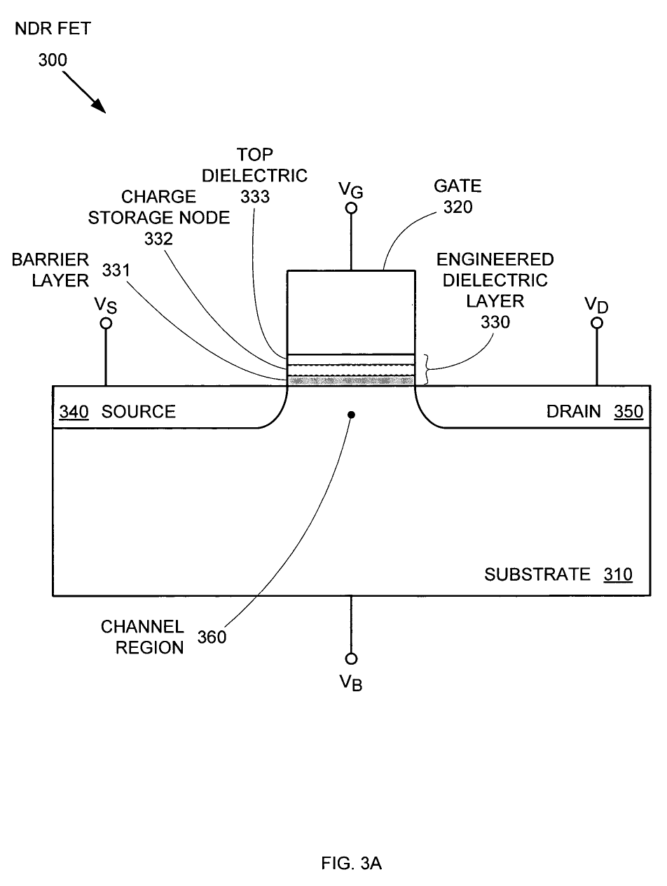

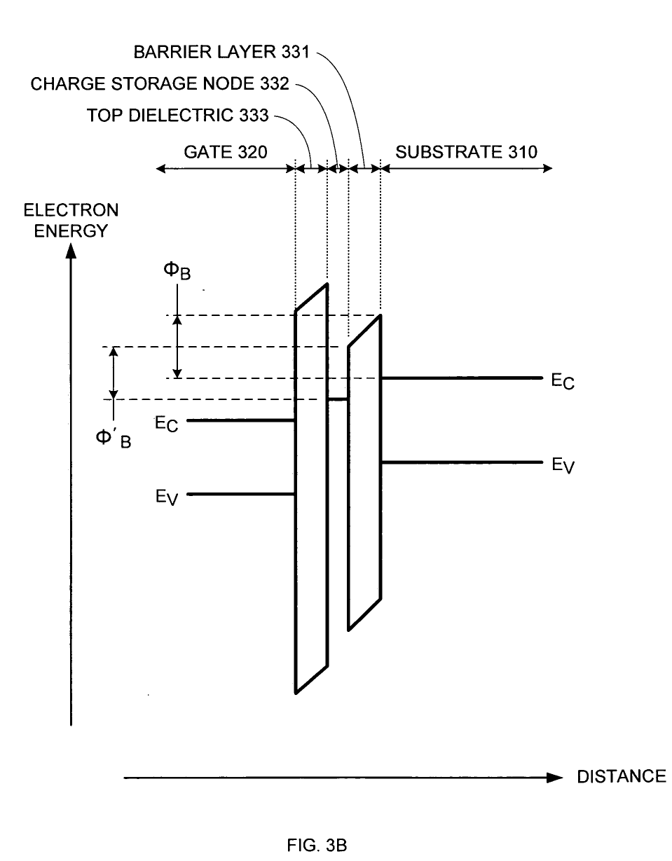

FIG. 3A shows an embodiment of an NDR field effect transistor (FET) 300 that includes a charge storage node 332 for providing the NDR characteristics of the device. NDR FET 300 includes a source 340 and a drain 350 formed in a substrate 310 (e.g., a silicon wafer). Note that while substrate 310 is depicted as a monolithic substrate for exemplary purposes, substrate 310 can comprise any type of semiconductor substrate (e.g., a silicon-on-insulator (SOI) substrate). A channel region 360 is defined in substrate 310 between source 340 and drain 350. An engineered dielectric layer 330 is formed over channel region 360, and a gate 320 is formed on engineered dielectric layer 330.

Engineered dielectric layer 330 includes a barrier layer 331 formed on channel region 360, a charge storage node 332 formed on barrier layer 331, and a top dielectric 333 formed on charge storage node 332. Top dielectric 333 can comprise any dielectric material used in field effect transistors (e.g., oxide or nitride). Barrier layer 331 is configured to dynamically transfer charge carriers between channel region 360 and charge storage node 332 in response to the electric field within channel region 360 (i.e., barrier layer 331 is selected to allow the concentration of charge carriers stored in charge storage node 332 to vary according to the magnitude of the electric field within channel region 360).

Thus, barrier layer 331 comprises a material having a relatively low potential barrier height to allow charge carriers in channel 360 having a certain minimum energy level to reach charge storage node 332. Barrier layer 331 will therefore generally have a much greater permittivity than top dielectric 333. If NDR FET 300 is an n-channel device, then barrier layer 331 can be selected to have a low electron potential barrier height. If NDR FET 300 is a p-channel device, then barrier layer 331 can be selected to have a low hole barrier height. Charge storage node 332 can comprise any material capable (e.g., metal, polycrystalline silicon, small metallic or semiconductor particles) of storing charge carriers passed by barrier layer 331. Note that in various other embodiments, charge storage node 332 can be eliminated (as indicated by the dotted lines around charge storage node 332), thereby allowing the barrier layer 331 itself to act as a charge storage node. Note that the vertical electric field is such that charges will be attracted to (and temporarily stored in the vicinity of) the interface between the top dielectric 333 and the barrier layer 331.

During operation of NDR FET 300, when a gate bias (i.e., a difference between a gate voltage V_{G} applied to gate 320 and a source voltage V_{S} applied to source 340) is large enough to turn on NDR FET 300 (i.e., form an inversion layer in channel region 360), mobile charge carriers in channel region 360 can begin flowing from source 340 to drain 350 in response to a drain-to-source voltage V_{DS} (i.e., a difference between a drain voltage V_{D} applied to drain 350 and source voltage V_{S}). As the drain-to-source voltage V_{DS} increases, the resultant electric field in channel region 360 increases, which initially increases the drain current I_{DS} flowing between source 340 and drain 350.

However, once the drain-to-source voltage V_{DS} reaches a threshold level (i.e., the NDR voltage for NDR FET 300), the kinetic energy imparted to the charge carriers by the electric field within channel region 360 is sufficient to allow some of those charge carriers to overcome the energy barrier at the interface between channel region 360 and barrier layer 331, thereby resulting in an accumulation of charge carriers within storage node 332. This accumulation of charge carriers increases the threshold voltage of NDR FET 300, thereby decreasing the current flow from source 340 to drain 350 (because the gate bias applied to NDR FET 300 remains unchanged).

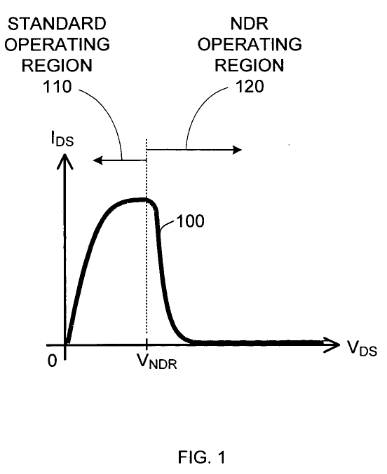

As the drain-to-source voltage V_{DS} increases, more energetic charge carriers are able to cross barrier layer 331, and the accumulation of charge carriers within storage node 332 increases, thereby further decreasing the current flow through NDR FET 300 (due to the increasing threshold voltage). If drain-to-source voltage V_{DS} decreases, the charge carrier concentration in storage node 332 decreases, thereby reducing the threshold voltage of NDR FET 300 and allowing the current flow through NDR FET 300 to rise back to standard operating mode levels. Thus, in contrast to a conventional floating gate transistor that provides essentially static charge storage in a floating gate (i.e., the concentration of storage charge remains constant regardless of drain-to-source voltage), NDR FET 300 can exhibit the NDR characteristic displayed by graph 100 in FIG. 1 due to the ability of barrier layer 331 to dynamically pass charge carriers between channel region 320 and storage node 332 in response to drain-to-source voltage V_{DS} (i.e., the ability to instantly and reversibly allow the concentration of charge carriers stored in storage node 332 to change in response to drain-to-source voltage V_{DS}).

As noted above, the NDR voltage for NDR FET 300 is the drain-to-source voltage V_{DS} at which sufficient energy is imparted to charge carriers in channel region 360 to allow those charge carriers to overcome the energy barrier at the interface between barrier layer 331 and channel region 360. Therefore, the NDR voltage for NDR FET 300 can be controlled by selecting barrier layer 331 to provide an appropriate potential barrier height between substrate 310 and charge storage node 332. By reducing the potential barrier height provided by barrier layer 331, the NDR voltage for NDR FET 300 can be reduced.

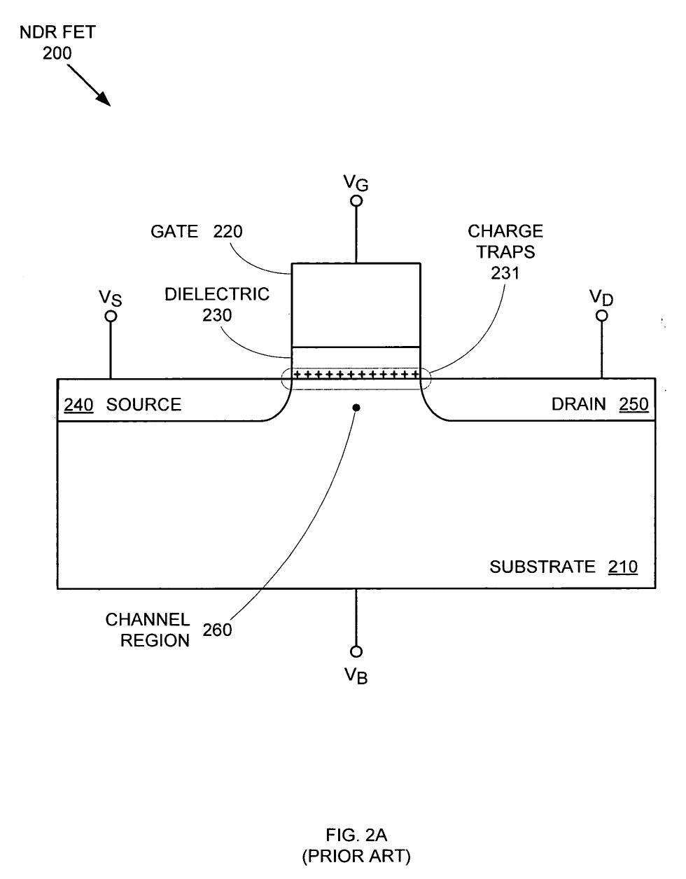

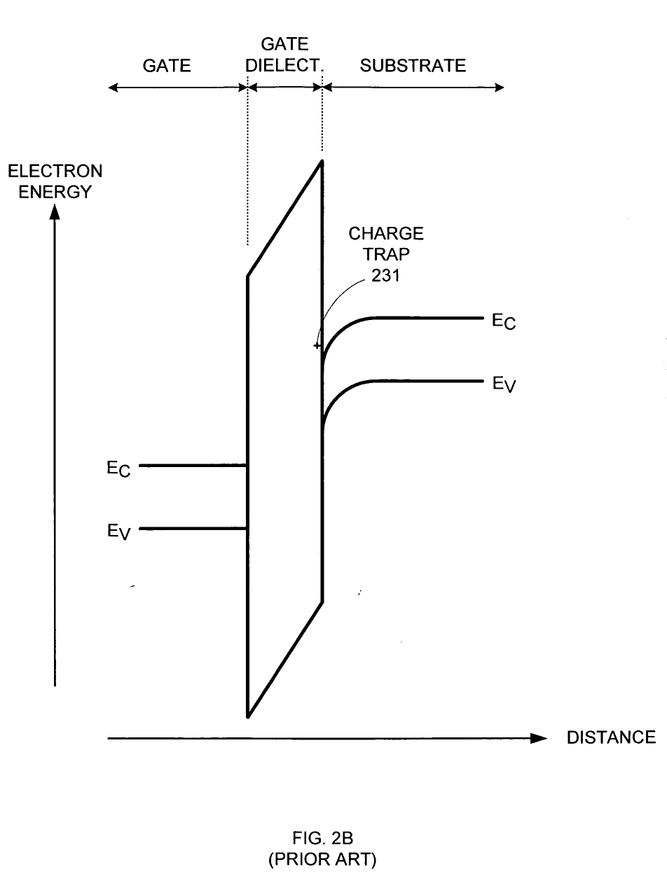

FIG. 3B shows an exemplary energy band diagram for NDR FET 300. A lower edge E_{C} for the conduction band of allowed electron energy states and an upper edge E_{V} for the valence band of allowed energy states are shown from gate 320 down to substrate 310. As noted above with respect to FIG. 2B, charge carriers cannot exhibit energy states within the band gap defined between edges E_{V} and E_{C}. The potential barrier height Φ_{B} from substrate 310 to barrier layer 331 defines the minimum energy that must be imparted to mobile charge carriers in NDR FET 300 before any such charge carriers can reach charge storage node 332 through barrier layer 331. Therefore, substrate-barrier layer potential barrier height Φ_{B} has a strong effect on modulating the NDR voltage for NDR FET 300. Specifically, a low substrate-barrier layer potential barrier height Φ_{B} will result in a low NDR voltage for NDR FET 300 by allowing charge carriers to be transferred to charge storage node 332 at a relatively low drain-to-source voltage V_{DS}.

Similarly, the potential barrier height Φ_{B}′ from charge storage node 332 to barrier layer 331 defines the minimum energy that must be gained (e.g. thermally) by a charge carrier held at charge storage node 332 before that charge carrier is released back into substrate 310 through barrier layer 331. Therefore, storage node-barrier layer potential barrier height Φ_{B}′ has a strong effect on modulating the NDR switching speed of NDR FET 300. Specifically, a lower storage node-barrier layer potential barrier height Φ_{B}′ will result in a fast NDR switching speed for NDR FET 300 by allowing more charge carriers stored at charge storage node 332 to be quickly released back into substrate 310.

Thus, the NDR performance characteristics of NDR FET 300 can be adjusted by appropriately engineering barrier layer 331 and charge storage node 332 to generate a relatively low substrate-barrier layer height Φ_{B} (to reduce NDR voltage) and/or a relatively storage node-barrier layer potential barrier height Φ_{B}′ (to increase NDR switching speed). In one embodiment, the process of defining appropriate characteristics for barrier layer 331 can involve first selecting a material for barrier layer 331 that provides a low substrate-barrier layer potential barrier height Φ_{B} for a given composition of substrate 310. Based on that barrier layer material, an appropriate material can then be selected for charge storage node 332 to achieve a low storage node-barrier layer potential barrier height Φ_{B}′.

For example, in one embodiment, an NMOS NDR FET (i.e., electrons as charge carriers) formed on a silicon substrate can include a titanium oxide (TiO₂) or hafnium oxide (HfO₂) barrier layer 331, and an n-doped polycrystalline silicon charge storage node 332 to provide low NDR voltage and fast NDR switching. Similarly, a PMOS NDR FET (i.e., holes as charge carriers) formed on a silicon substrate can include a hafnium oxide barrier layer 331, and a p-doped polycrystalline silicon charge storage node 332. Note that these material combinations are provided for exemplary purposes, and various other material combinations will be readily apparent.

Source Trapping Enhancement

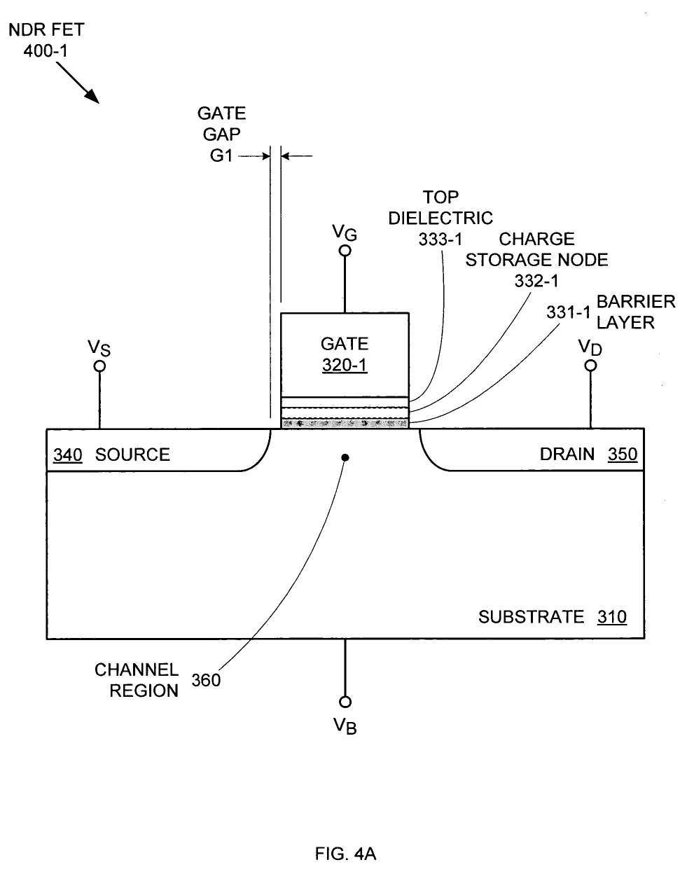

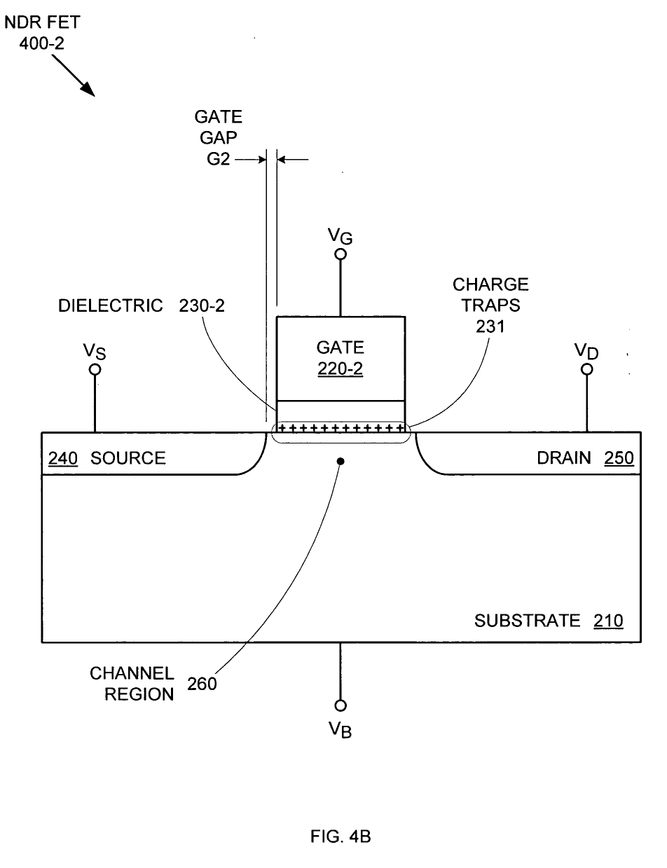

FIG. 4A shows an NDR FET 400-1 that incorporates source-side charge trapping enhancement to improve NDR performance. Specifically, NDR FET 400-1 is substantially similar to NDR FET 300 in FIG. 3A, except that the gate stack formed by gate 320-1, top dielectric 333-1, charge storage node 332-1, and barrier layer 331-1 in NDR FET 400-1 does not extend all the way to the edge of source region 340 (i.e., the gate stack does not cover the portion of channel region 360 immediately adjacent to source region 340). Therefore, a gate gap G1 exists in channel region 360 between the edge of source region 340 and the edge of gate 320-1. Note that for manufacturability purposes, a similar gate gap will typically be formed between the gate stack and drain region 350, although in other embodiments, the gate stack can extend up to and beyond the edge of drain region 350.

The presence of gate gap G1 means that although an appropriate gate bias will form an inversion layer in the region of gate gap G1, channel formation in that region will typically not be as well-defined as in the portions of channel region 360 directly under gate 320-1. Therefore, when current is flowing through channel region 360, much of the voltage drop between source region 340 and drain region 350 will occur at gate gap G1. Consequently, the electric field in channel region 360 will be highest in the region of gate gap G1.

As a result of this “source-weighted” electric field in channel region 360, charge trapping in charge storage node 332-1 can occur more readily towards the source side of the barrier layer 331-1/charge storage node 332-1 stack. This charge trapping bias towards source 340 beneficially allows NDR FET 400-1 to exhibit a lower NDR voltage and faster switching speed for a given gate stack construction, because the concentrated charge trapping in close proximity to source 340 provides a more immediate effect on threshold voltage V_{TH} than does the more evenly distributed charge trapping provided by a gate stack that has no gap between the edges of the gate stack and source region. In addition, the lower NDR voltage can improve the “off” current exhibited by NDR FET 400-1, thereby beneficially increasing the PVR of NDR FET 400-1.

Note that while NDR FET 400-1 is depicted as having a gate stack that includes barrier layer 331-1 and charge storage node 332-1 for exemplary purposes, the benefits of providing gate gap G1 can be applied to any NDR FET construction, regardless of the mechanism for charge trapping. For example, FIG. 4B shows an NDR FET 400-2 that is substantially similar to NDR FET 200 shown in FIG. 2A, except that the gate stack formed by gate 200-2 and dielectric 230-2 does not extend all the way to the edge of source 240 (a similar gap is depicted between the gate stack and the edge of drain 250, although in various other embodiments, the gate stack may extend to or overlap drain 250). Just as described with respect to FIG. 4A, the resulting gate gap G2 produces an enhanced electric field in channel region 260 that enables increased charge trapping in the charge traps 231 of dielectric 230-2 that are closer to source 240, thereby providing reduced NDR voltage, increased NDR switching speed, and increased PVR for NDR FET 400-2.

The various embodiments of the structures and methods of this invention that are described above are illustrative only of the principles of this invention and are not intended to limit the scope of the invention to the particular embodiments described. For example, in various embodiments, channel regions 260 and 360 in FIGS. 2A and 3A, respectively, can be mechanically strained to enhance carrier mobility, and hence improve PVR, switching speed, and/or NDR voltage for NDR FETs 200 and 300, respectively. Thus, the invention is limited only by the following claims and their equivalents.

1. A transistor comprising:
a source region formed in a substrate;
a drain region formed in the substrate;
a channel region in the substrate between the source region and the drain region;
a barrier layer formed on the substrate over the channel region;
a dielectric layer formed over the barrier layer; and
a gate formed on the dielectric layer,
wherein the barrier layer is configured to dynamically transfer charge carriers to and from the channel region in response to a drain-to-source voltage applied across the drain region and the source region.

2. The transistor of claim 1, wherein the transistor exhibits a negative differential resistance characteristic in response to variations in the drain-to-source voltage.

3. The transistor of claim 1, wherein a permittivity of the barrier layer is greater than a permittivity of the dielectric layer.

4. The transistor of claim 1, further comprising a charge storage layer interposed between the barrier layer and the dielectric layer.

5. The transistor of claim 4, wherein the transistor comprises an n-channel transistor, and wherein the charge carriers comprise electrons.

6. The transistor of claim 5, wherein the substrate comprises silicon,
wherein the barrier layer comprises one of a titanium oxide layer and a hafnium oxide layer, and
wherein the charge storage layer comprises an n-doped polycrystalline-silicon layer.

7. The transistor of claim 4, wherein the transistor comprises a p-channel transistor, and
wherein the charge carriers comprises holes.

8. The transistor of claim 7, wherein the substrate comprises silicon,
wherein the barrier layer comprises a hafnium oxide layer, and
wherein the charge storage layer comprises a p-doped polycrystalline-silicon layer.

9. The transistor of claim 1, wherein the gate does not overlie a first portion of the channel region, the first portion of the channel region being immediately adjacent to the source region.

10. A transistor comprising:
a source region formed in a substrate;
a drain region formed in the substrate;
a channel region in the substrate between the source region and the drain region;
a barrier layer formed on the substrate over the channel region;
a dielectric layer formed over the barrier layer; and
a gate formed on the dielectric layer,
wherein a first potential barrier height between the channel region and the barrier layer is less than a second potential barrier height between the channel region and the dielectric layer.

11. The transistor of claim 10, wherein the transistor exhibits a negative differential resistance characteristic in response to variations in a drain-to-source voltage applied across the drain region and the source region.

12. The transistor of claim 11, wherein the barrier layer is configured to dynamically transfer charge carriers to and from the channel region in response to the drain-to-source voltage.

13. The transistor of claim 10, further comprising a charge storage layer interposed between the barrier layer and the dielectric layer.

14. The transistor of claim 13, wherein the transistor comprises an n-channel transistor,
wherein the substrate comprises silicon,
wherein the barrier layer comprises one of a titanium oxide layer and a hafnium oxide layer, and
wherein the charge storage layer comprises an n-doped polycrystalline-silicon layer.

15. The transistor of claim 13, wherein the transistor comprises a p-channel transistor,
wherein the substrate comprises silicon,
wherein the barrier layer comprises a hafnium oxide layer, and
wherein the charge storage layer comprises a p-doped polycrystalline-silicon layer.

16. The transistor of claim 10, wherein the gate does not overlie a first portion of the channel region, the first portion of the channel region being immediately adjacent to the source region.

17. A negative differential resistance (NDR) transistor comprising:
a source region formed in a substrate;
a drain region formed in the substrate;
a channel region in the substrate between the source region and the drain region; and
a gate stack formed over the channel region,
wherein the gate stack does not overlie a first portion of the channel region immediately adjacent to the source region.

18. The NDR transistor of claim 17, wherein the gate stack does not overlie a second portion of the channel region immediately adjacent to the drain region.

19. The NDR transistor of claim 17, wherein the gate stack comprises:
a barrier layer;
a dielectric layer formed over the barrier layer; and
a gate formed on the dielectric layer,
wherein the barrier layer is configured to dynamically transfer charge carriers to and from the channel region in response to a drain-to-source voltage applied across the drain region and the source region.

20. The NDR transistor of claim 19, wherein the gate stack further comprises a charge storage layer interposed between the barrier layer and the dielectric layer.

21. The NDR transistor of claim 17, wherein the gate stack comprises:
a barrier layer;
a dielectric layer formed over the barrier layer; and
a gate formed on the dielectric layer,
wherein a permittivity of the barrier layer is greater than a permittivity of the dielectric layer.

22. The NDR transistor of claim 17, wherein the gate stack comprises:
a dielectric layer; and
a gate formed on the dielectric layer,
wherein the dielectric layer is configured to dynamically trap and detrap charge carriers from the channel region in response to a drain-to-source voltage applied across the drain region and the source region.

23. The NDR transistor of claim 22, wherein the dielectric layer comprises a plurality of charge traps.
